(19) United States
(12) Patent Application Publication
(10) Pub. No.: US 2016/0329275 A1
(43) Pub. Date: Nov. 10, 2016

(54) PACKAGE SUBSTRATE AND METHODS FOR MANUFACTURING THE SAME

(71) Applicant: Samsung Electronics Co., Ltd., Suwon-si (KR)

(72) Inventors: Soojae PARK, Asan-si (KR); Moon Gi CHO, Gunpo-si (KR)

(21) Appl. No.: 15/146,664

(22) Filed: May 4, 2016

(30) Foreign Application Priority Data
May 7, 2015 (KR) 10-2015-0063970

(51) Int. Cl. H01L 23/498; H01L 23/00

(52) U.S. Cl. CPC H01L 23/49838; H01L 23/49811; H01L 23/49866; H01L 23/49822; H01L 24/48; H01L 2924/01028; H01L 2924/01013; H01L 2924/01022; H01L 2924/01073; H01L 2924/01079; H01L 2924/01047; H01L 2924/01074; H01L 2924/04941; H01L 2924/04953; H01L 23/4985; H01L 2924/01029; H01L 2224/48091; H01L 2224/48106; H01L 2224/48228; H01L 2924/15747; H01L 2924/15738

(57) ABSTRACT

The present inventive concept provides a package substrate. The package substrate comprises an insulating substrate having a top surface a circuit pattern disposed on the top surface, and a multilayer conductive joint unit disposed on the circuit pattern. The multilayer conductive joint unit comprises a nickel layer which is in contact with the circuit pattern, and an aluminum layer disposed on the nickel layer and connected to a semiconductor chip mounted on the insulating substrate.

### CROSS-REFERENCE TO RELATED APPLICATIONS

This U.S. non-provisional patent application claims priority under 35 U.S.C. §119 of Korean Patent Application No. 10-2015-0063970, filed on May 7, 2015, the entire contents of which are hereby incorporated by reference.

### BACKGROUND

The inventive concept relates to packages, and more particularly, to a package substrate surface-treated using aluminum and a semiconductor package including such package substrate.

As an electronic component has a high density, various surface treatment technologies for a printed circuit board (PCB) have been developed. A metal plating method as one of the surface treatment technologies for the PCB has been used. The metal plating method may include an electroplating method and an electroless metal plating method. As the PCB has become higher in component density and the metal plating layer has become thinner, a surface of the PCB has been electroless-treated in order to simplify a process for the PCB and reduce a noise in the PCB.

Since an electroless nickel immersion gold (ENIG), and an electroless nickel electroless palladium immersion gold (ENEPIG) have a good solder joint reliability and a good wire bonding reliability, they have been used in various fields as well as in PCB and a package substrate.

### SUMMARY

According to one aspect of the inventive concept, a package substrate is provided. The package substrate includes an insulating substrate having a top surface and a bottom surface, a circuit pattern disposed on at least one of the top surface of the insulating substrate, and a multilayer conductive joint unit disposed on the circuit pattern. The multilayer conductive joint unit comprises a nickel layer which is in contact with the circuit pattern, and an aluminum layer on the nickel layer and connected to a semiconductor chip mounted on the insulating substrate.

In one embodiment of the inventive concept, the multilayer conductive joint unit further comprises a metal layer between the nickel layer and the aluminum layer.

In another embodiment of the inventive concept, the metal layer comprises titanium (Ti), tantalum (Ta), titanium nitride (TiN), tantalum nitride (TaN), gold (Au), silver (Ag), or tungsten (W).

In another embodiment of the inventive concept, a thickness of the contact pad is 0.1 μm˜1 μm.

In another embodiment of the inventive concept, the insulating substrate comprises a core unit, an upper interconnection layer disposed on a top surface of the core unit, an upper insulating layer disposed on the upper interconnection layer, a lower interconnection layer disposed on a bottom surface of the core unit, and a lower insulating layer disposed on the lower interconnection layer.

In another embodiment of the inventive concept, the nickel layer is an electroless plating layer.

In another embodiment of the inventive concept, the insulating substrate further comprises a solder resist layer disposed on the circuit pattern. The solder resist layer has a hole exposing a part of the circuit pattern.

In another embodiment of the inventive concept, the nickel layer and the aluminum layer are disposed inside the hole of the solder resist layer.

In another embodiment of the inventive concept, the nickel layer is provided to cover a top surface and a side surface of the circuit pattern.

In another embodiment of the inventive concept, the nickel layer is provided to cover a part of a top surface of the circuit pattern.

In another embodiment of the inventive concept, the substrate comprises a PCB (printed circuit board) or a flexible PCB.

According to another aspect of the inventive concept, a package substrate is provided. The package substrate comprises a copper pad, an insulating layer, and a multilayer conductive joint unit. The copper pad is disposed on a top surface of the insulating layer. The joint unit comprises a nickel layer in contact with the copper pad, and a contact pad disposed on the nickel layer. The contact pad includes metallic compound including aluminum.

In one embodiment of the inventive concept, the contact pad is made of Al or Al—Cu.

In another embodiment of the inventive concept, the multilayer conductive joint unit further comprises a metal layer disposed between the nickel layer and the contact pad. The metal layer comprises titanium (Ti), tantalum (Ta), titanium nitride (TiN), tantalum nitride (TaN), gold (Au), silver (Ag), or tungsten (W).

In another embodiment of the inventive concept, the multilayer conductive joint unit further comprises an aluminum oxide layer formed on a top surface of the contact pad. The bonding wire penetrates the aluminum oxide layer to electrically connect the contact pad and the semiconductor chip.

In another embodiment of the inventive concept, the package substrate further comprises a semiconductor chip mounted on the package substrate. The semiconductor chip is electrically connected to the package substrate by a bonding wire, and the bonding wire penetrates the aluminum oxide layer to electrically connect the contact pad and the semiconductor chip.

In another embodiment of the inventive concept, the package substrate further comprises a solder resist layer disposed on the copper pad and the insulating layer. The solder resist layer exposes a part of the copper pad and a side wall of the hole surrounds the multilayer conductive joint unit.

According to another aspect of the inventive concept, a package substrate is provided. The package substrate comprises a core unit, an insulation layer disposed on the core unit, a circuit pattern disposed on the insulation layer, and a multilayer conductive joint unit disposed on the circuit pattern. The multilayer conductive joint unit comprises a bottom conductive layer and a contact pad. The bottom conductive layer is in contact with the circuit pattern.

In another embodiment, the bottom layer of the multilayer conductive joint unit comprises a nickel layer, and the multilayer conductive joint further includes a middle metal layer between the nickel layer and the contact pad to increase an adhesive strength between the nickel layer and the contact pad.

In another embodiment, the package substrate further comprises a solder resist layer disposed on the insulating layer and the circuit pattern. The solder resist layer includes a hole exposing a top surface of at least a part of the circuit pattern and the multilayer conductive joint is disposed inside the hole.

In another embodiment, the package substrate further comprises a solder resist layer disposed on the circuit pattern. The solder resist layer includes a hole exposing a top surface and a side surface of a pad of the circuit pattern. The nickel layer covers the top surface and the side surface of the pad of the circuit pattern, the contact pad covers a top and a side surface of the nickel layer such that a side surface of the contact pad contacts sidewalls of the hole, and a top surface of the contact pad is exposed to air to form the aluminum oxide layer.

In another embodiment, the contact pad is made of Al, Al—Cu, Al—Si or Al—Cu-Si.

According to another aspect of the inventive concept a method of manufacturing a package substrate is provided. The method includes forming a solder resist layer on an insulating layer and a circuit pattern disposed on the insulating layer so that a part of the circuit pattern is exposed, forming a nickel layer electrically connected to the exposed circuit pattern, and forming a contact pad on the nickel layer. The contact pad is wire-bonded to a semiconductor chip mounted on the package substrate.

In one embodiment of the inventive concept, the contact pad is formed by an inkjet method.

In another embodiment of the inventive concept, the inkjet method includes coating the nickel layer with an aluminum precursor or aluminum nano particles.

In another embodiment of the inventive concept, the contact pad is formed by a plating method using an ionic liquid and an organic solution, a dipping process, a screening process or a slot die process.

In another embodiment of the inventive concept, the contact pad is formed by a sputtering method.

In another embodiment of the inventive concept, the bonding wire is connected to the contact pad by penetrating an aluminum oxide layer formed on the contact pad.

### BRIEF DESCRIPTION OF THE FIGURES

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Similar numbers refer to similar elements throughout.

FIG. 1 is a cross sectional view illustrating a semiconductor package in accordance with an embodiment of the inventive concept.

FIG. 2 is an enlarged cross sectional view of ‘A’ area of FIG. 1.

FIGS. 3A through 3E are cross sectional views illustrating a manufacturing a semiconductor package in accordance with an embodiment of the inventive concept.

FIG. 4 is a cross sectional view illustrating a part of a semiconductor package in accordance with an embodiment of the inventive concept.

FIG. 5 is a cross sectional view illustrating a part of a semiconductor package in accordance with another embodiment of the inventive concept.

FIG. 6 is a block diagram illustrating an example of an electronic device having a semiconductor package in accordance with an embodiment of the inventive concept.

FIG. 7 is a block diagram illustrating an example of a memory system having a semiconductor package in accordance with an embodiment of the inventive concept.

### DETAILED DESCRIPTION

Embodiments of inventive concepts will be described more fully hereinafter with reference to the accompanying drawings, in which embodiments of the invention are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

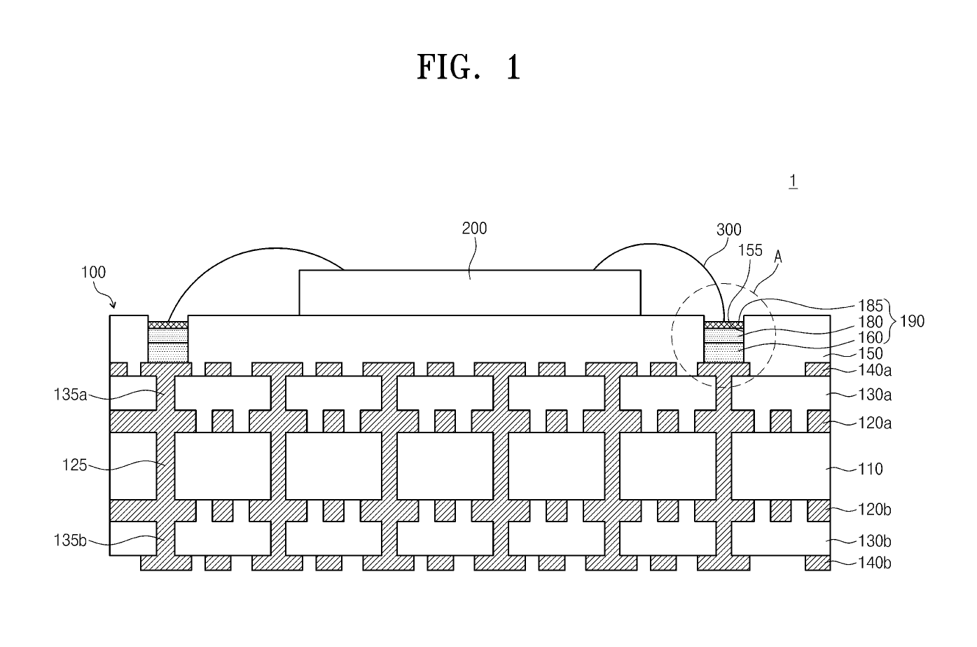

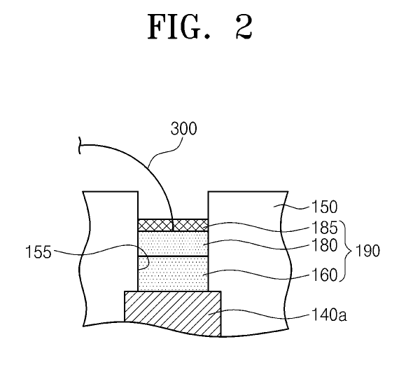

FIG. 1 is a cross sectional view illustrating a semiconductor package in accordance with an embodiment of the inventive concept. FIG. 2 is an enlarged cross sectional view of ‘A’ area of FIG. 1.

Referring to FIGS. 1 and 2, a semiconductor package 1 may include a package substrate 100, a semiconductor chip 200 and a bonding wire 300.

In some embodiments, the package substrate 100 may include an insulating substrate having a top surface and a bottom surface, circuit patterns 140a, 140b disposed on the top surface and the bottom surface of the insulating layer respectively; and a multilayer conductive joint unit 190 disposed on the circuit patterns,

In some embodiments, the package substrate 100 may include a core unit 110, interconnection layers 120a and 120b, insulation layers 130a and 130b, circuit patterns 140a and 140b, and a multilayer conductive joint unit 190. In some embodiments, the package substrate 100 may be a PCB (printed circuit board) or a flexible substrate.

The core unit 110 may include a resin and a glass fiber. The glass fiber may be one of reinforcing materials and may be obtained by twisting hundreds of strands of glass filaments having a diameter of 5 μm˜15 μm to make a fiber bundle and then weaving the fiber bundle. The glass filament may be ore products whose main ingredient is silica. The glass fiber may have superior heat resistance, superior mechanical strength and superior electric insulation. Alternatively, the package substrate 100 may be a PCB (printed circuit board) or a flexible substrate, which do not include the core unit 110.

The interconnection layers 120a and 120b may be disposed on the core unit 110. The interconnection layers 120a and 120b may include or be made of plating material such as nickel (Ni) or copper (Cu), or polymer having superior thermal conductive property. The interconnection layers 120a and 120b may include an upper interconnection layer 120a disposed on a top surface of the core unit 110 and a lower interconnection layer 120b disposed on a bottom surface of the core unit 110. The upper interconnection layer 120a and the lower interconnection layer 120b may be electrically connected to each other through a first via 125. The first via 125 may penetrate the core unit 110. The first via 125 may include or be made of plating material such as nickel (Ni) or copper (Cu), or polymer having superior thermal conductive property.

The insulation layers 130a and 130b may be disposed on the interconnection layers 120a and 120b, respectively. The insulation layers 130a and 130b may include or be made of resin. The insulation layers 130a and 130b may include an upper insulation layer 130a disposed on the upper interconnection layer 120a and a lower insulation layer 130b disposed on the lower interconnection layer 120b.

The circuit patterns 140a and 140b may be disposed on the insulation layers 130a and 130b, respectively. The circuit patterns 140a and 140b may include or be made of copper (Cu). The circuit patterns 140a and 140b may include an upper circuit pattern 140a disposed on the upper insulation layer 130a and a lower circuit pattern 140b disposed on the lower insulation layer 130b. The upper circuit pattern 140a and the upper interconnection layer 120a may be electrically connected to each other through a second via 135a. The second via 135a may penetrate the upper insulation layer 130a. The lower circuit pattern 140b and the lower interconnection layer 120b may be electrically connected to each other through a third via 135b. The third via 135b may penetrate the lower insulation layer 130b. The second via 135a and the third via 135b may include or be made of plating material such as nickel (Ni) or copper (Cu), or polymer having superior thermal conductive property.

A solder resist layer 150 may be disposed on the upper circuit pattern 140a. The solder resist layer 150 may include a hole 155 exposing a part of a top surface of the upper circuit pattern 140a. The solder resist layer 150 may include or be made of an insulating coating layer. The solder resist layer 150 may protect the upper circuit pattern 140a and may prevent a bridge phenomenon from occurring between the upper circuit patterns 140a.

The multilayer conductive joint unit 190 may be disposed inside the hole 155. The sidewall of the hole 155 may surround or be in contact with side surfaces of the multilayer conductive joint unit 190. In some embodiments, the multilayer conductive joint unit 190 may include a bottom conductive layer disposed on the upper circuit pattern 140a and a contact pad 180 disposed on the nickel layer 160. In some embodiments, the bottom conductive layer may include a nickel layer 160 contact pad. The nickel layer 160 can prevent copper (Cu) from being diffused between the upper circuit pattern 140a and the contact pad 180. The nickel layer 160 may include phosphorus to prevent oxidation of nickel (Ni) included in the nickel layer 160. For example, the nickel layer 160 may include phosphorus of 5 wt %˜12 wt %. A width of the nickel layer 160 may be smaller than width of the upper circuit pattern 140a. A thickness of the nickel layer 160 may be 2 μm˜8 μm.

The contact pad 180 may include or be made of aluminum (Al) or metallic compound including aluminum (Al). For example, the contact pad 180 may comprise Al—Si, Al—Cu or Al—Cu-Si. The contact pad 180 may include a small amount of Silicon and Copper. Silicon may control a size of aluminum crystals contained within the contact pad 180. Copper may prevent migration of aluminum contained within the contact pad 180. A thickness of the contact pad 180 may be 0.1 μm˜1 μm. The contact pad 180 can prevent oxidation of the nickel layer 160 and may be connected to the semiconductor chip 200 by the wire bonding. Since a stable aluminum oxide layer 185 is naturally formed on a surface of the contact pad 180, defects such as a surface discoloration may not occur. For example, the aluminum oxide layer 185 formed may comprise alumina (Al₂O₃). Aluminum (Al) has good electrical conductivity, is inexpensive. When aluminum is used to replace gold (Au) in a conventional ENIG (electroless nickel immersion gold), the manufacturing cost of the package substrate can be reduced.

The semiconductor chip 200 may be disposed on the package substrate 100. The semiconductor chip 200 may be a logic chip, a memory chip, or combinations thereof.

The bonding wire 300 can electrically connect the package substrate 100 and the semiconductor chip 200. The bonding wire 300 may include or be made of copper (Cu) or gold (Au). The bonding wire 300 can electrically connect a top surface of the semiconductor chip 200 and the contact pad 180 of the package substrate 100. Aluminum has good electrical conductivity but has a high oxidation characteristic. Accordingly, the aluminum oxide layer 185 may be formed at a portion where the contact pad 180 is exposed to air. The aluminum oxide layer 185 may obstruct an electrical connection between the bonding wire 300 and the contact pad 180. Thus, the bonding wire 300 may penetrate the aluminum oxide layer 185 to be directly connected to the contact pad 180.

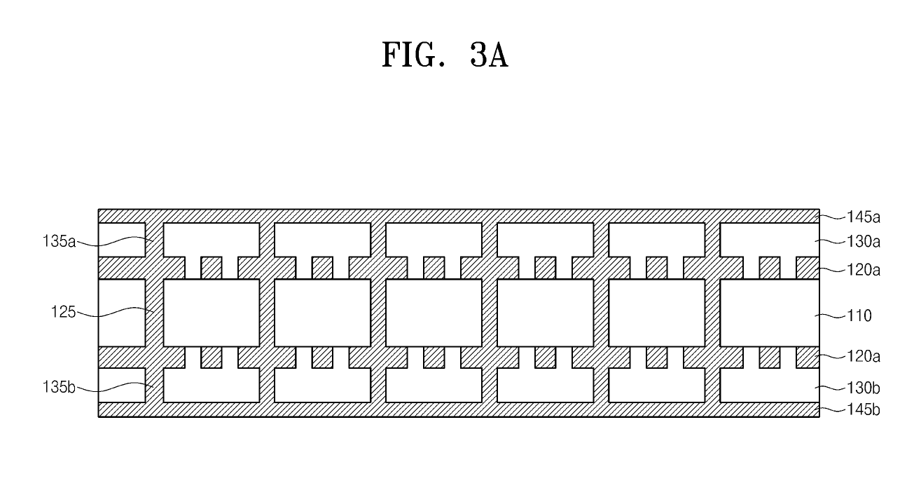

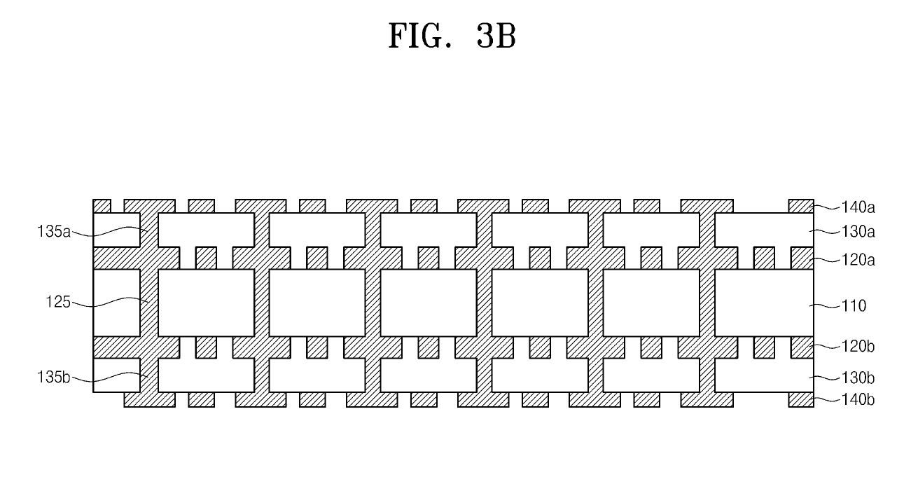

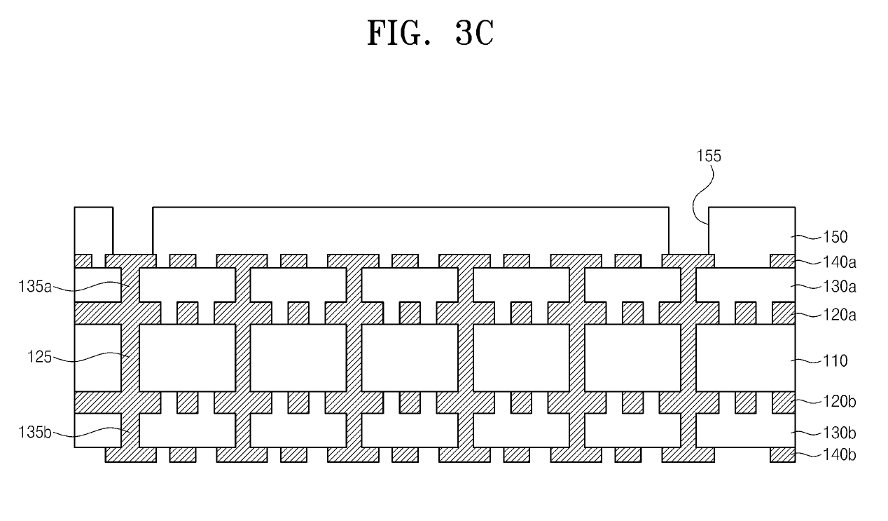

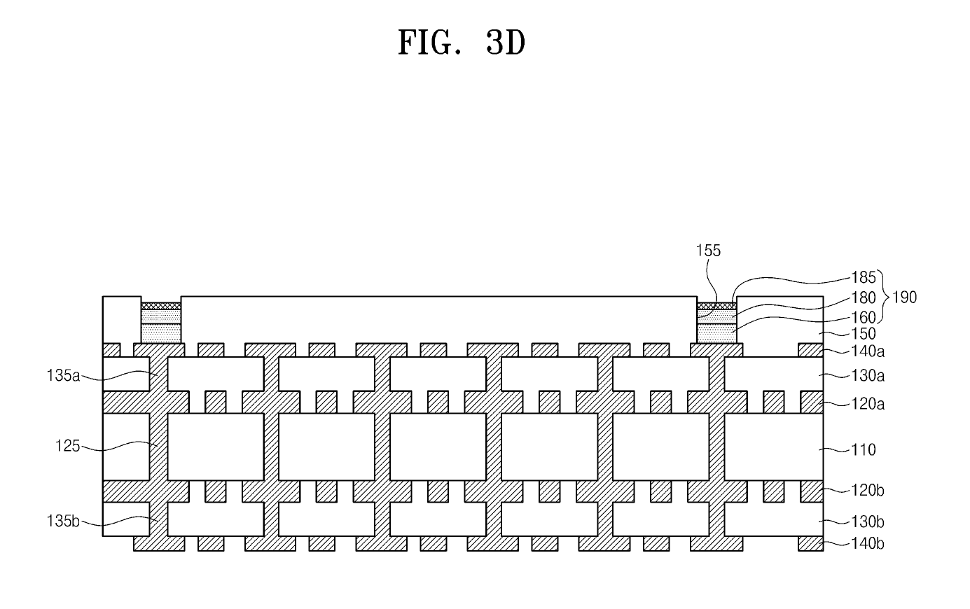

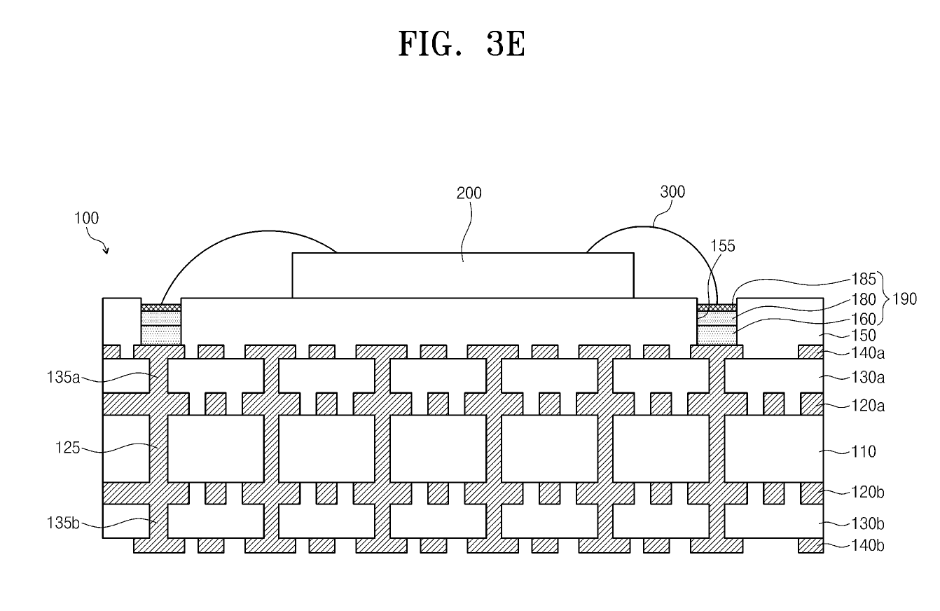

FIGS. 3A through 3E are cross sectional views illustrating a manufacturing a semiconductor package in accordance with an embodiment of the inventive concept.

Referring to FIG. 3A, interconnection layers 120a and 120b, insulation layers 130a and 130b and circuit patterns 140a and 140b may be sequentially formed on a core unit 110. An upper interconnection layer 120a may be formed on a top surface of the core unit 110 and a lower interconnection layer 120b may be formed on a bottom surface of the core unit 110. The upper interconnection layer 120a and the lower interconnection layer 120b may be electrically connected to each other through a first via 125. The first via 125 may be formed to penetrate the core unit 110. The first via 125 may be formed by forming a via hole using a laser drilling process and then filling the via hole with conductive material. The conductive material may be plating material such as nickel (Ni) or copper (Cu), or polymer having superior thermal conductive property.

The insulation layers 130a and 130b may be formed by coating insulation material on the upper interconnection layer 120a and the lower interconnection layer 120b and then hardening the insulation material. The upper insulation layer 130a and the lower insulation layer 130b may be formed on the upper interconnection layer 120a and the lower interconnection layer 120b, respectively. The insulation material may include or be made of resin.

Circuit layers 145a and 145b may be formed on the insulation layers 130a and 130b, respectively. An upper circuit layer 145a may be formed on the upper insulation layer 130a and a lower circuit layer 145b may be formed on the lower insulation layer 130b. The circuit layers 145a and 145b may include or be made of copper (Cu).

Referring to FIG. 3B, the circuit layers 145a and 145b may be patterned to form the circuit patterns 140a and 140b, respectively. For example, the circuit layers 145a and 145b may be patterned using a photo process and an etching process to form the circuit patterns 140a and 140b. The circuit patterns 140a and 140b may include an upper circuit pattern 140a formed on the upper insulation layer 130a and a lower circuit pattern 140b formed on the lower insulation layer 130b.

Referring to FIG. 3C, a solder resist layer 150 may be formed on the upper insulation layer 130a and the upper circuit pattern 140a. The solder resist layer 150 may be made by a photoimageable solder resist (PSR) coating. The solder resist layer 150 can protect the upper circuit pattern 140a and may prevent a bridge phenomenon from occurring between adjacent upper circuit patterns 140a. After forming the solder resist layer 150, an etching process is performed so that a part of top surface of the upper circuit pattern 140a is exposed to form a hole 155.

Referring to FIG. 3D, in some embodiments, a nickel layer 160 and a contact pad 180 may be sequentially formed on the upper circuit pattern 140a exposed by the hole 155. A side of the nickel layer 160 and the contact pad 180 may be surrounded by the sidewall of the hole 155. The nickel layer 160 may be an electroless plating layer formed by an electroless plating method. The nickel layer 160 may include phosphorus to prevent oxidation of nickel (Ni) included in the nickel layer 160. For example, the nickel layer 160 may include phosphorus of 5 wt %˜12 wt %. The contact pad 180 may be formed on the nickel layer 160. A thickness of the contact pad 180 may be 0.1 μm˜1 μm.

The contact pad 180 may be formed through an inkjet method, a physical vapor deposition (PVD) method, a plating method using an ionic liquid and an organic solution, a dipping process, a screening process, or a slot die process. The inkjet method may be a method of coating the nickel layer 160 with an aluminum precursor or aluminum nano particles. For example, the aluminum precursor may be alanate (AlH₃). The alanate (AlH₃) is easily decomposed into aluminum (Al) and hydrogen (H₂) at a low temperature (e.g., 150° C.). The alanate (AlH₃) may be decomposed at a room temperature using a proper catalyst. Thus, aluminum is easily embodied as an electrical circuit and an electrode using the alanate (AlH₃). Alternatively, the contact pad 180 may be formed by coating and then drying the aluminum precursor and the aluminum nano particles.

The slot die process may be a process of applying metallic liquid using a pulsation free pump pulsate or a piston pump. Aluminum can be coated in a uniform thickness using the slot die process.

The screening process may be a process of using a metallic fluid as ink and putting a pressure using a roller.

The dipping process may be a process of dipping a substance into a molten metal (for example, aluminum) to coat the substance with the molten metal.

The plating method using an ionic liquid and an organic solution, and a physical vapor deposition (PVD) method may be performed by the conventional method.

Referring to FIG. 3E, the package substrate 100 and the semiconductor chip 200 can be electrically connected to each other through the bonding wire 300. The bonding wire 300 may be copper (Cu) or gold (Au) having a high electrical conductivity. The wire bonding process may ball-bond the bonding wire 300 onto the semiconductor chip 200 and may stitch-bond the bonding wire 300 onto the contact pad 180. The stitch bonding is a process of vibrating the bonding wire 300 with high frequency vibrations to bond the bonding wire 300. The bonding wire 300 can penetrate the aluminum oxide layer 185 formed on the contact pad 180 through the stitch bonding and can electrically connect the contact pad 180 and the semiconductor chip 200.

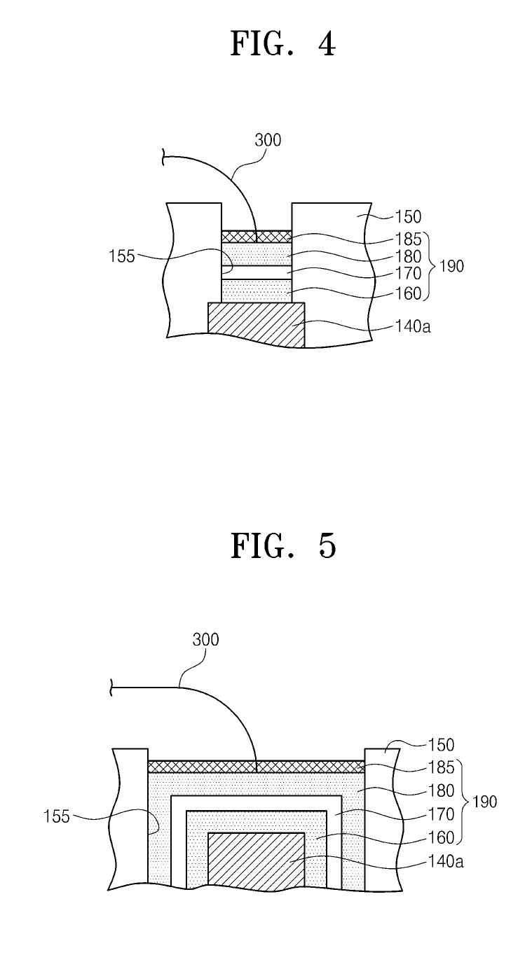

FIG. 4 is a cross sectional view illustrating a part of a semiconductor package in accordance with an embodiment of the inventive concept.

Referring to FIG. 4, a metal layer 170 may be provided between the nickel layer 160 and the contact pad 180. The metal layer 170 can increase an adhesive strength between the nickel layer 160 and the contact pad 180. For example, the metal layer 170 may include titanium (Ti), tantalum (Ta), titanium nitride (TiN), tantalum nitride (TaN), gold (Au), silver (Ag), or tungsten (W). The metal layer 170 may be formed on the nickel layer 160 and may be formed by a conventional electroplating method or an electroless plating method. Side surfaces of the nickel layer 160, the metal layer 170 and the contact pad 180 may contact the sidewall of the hole 155.

FIG. 5 is a cross sectional view illustrating a part of a semiconductor package in accordance with another embodiment of the inventive concept.

Referring to FIG. 5, the solder resist layer 150 may include the hole 155. The hole 155 exposes a top surface and a side surface of the upper circuit pattern 140a. The nickel layer 160 may be formed to cover the top surface and the side surface of the upper circuit pattern 140a. The metal layer 170 may be formed to cover a top surface and a side surface of the nickel layer 160. The contact pad 180 may be formed to cover a top surface and a side surface of the metal layer 170. In some embodiments, a side surface of the contact pad 180 contacts a sidewall of the hole 155 and a top surface of the contact pad 180 may be exposed to air. An aluminum oxide layer 185 may be formed on a top surfaced of the contact pad 180 when the top surfaced of the contact pad 180 is exposed to air. The side surfaces of the contact pad 180 and the aluminum oxide layer 185 may contact the sidewall of the hole 155.

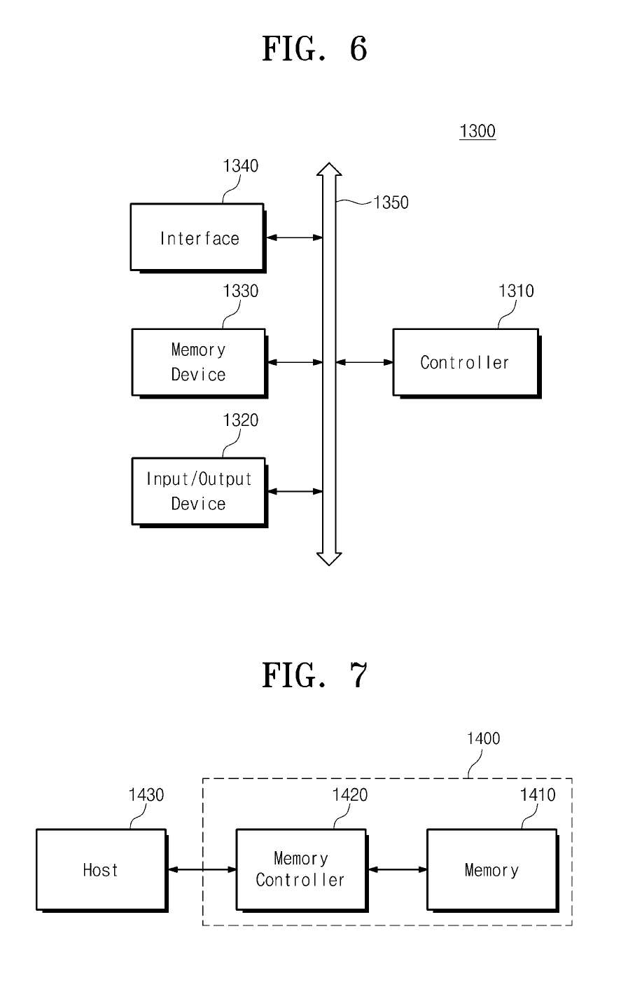

FIG. 6 is a block diagram illustrating an example of an electronic system including a semiconductor package in accordance with an embodiment of the inventive concept.

The semiconductor package describe above may be applied to the electronic system. The semiconductor package may be provided in the form of memory device. Referring to FIG. 6, the electronic system 1300 may include a controller 1310, an input/output device 1320, and a memory device 1330. The controller 1310, the input/output device 1320, and the memory device 1330 may be connected with one another through a bus 1350. The bus 1350 may be a path through which data moves. The controller 1310 may include at least one of a microprocessor, a digital signal processor, and a microcontroller and at least one of logic devices having a function similar to the microprocessor, the digital signal processor and the microcontroller. The controller 1310 and/or the memory device 1330 may include a semiconductor package according to the present invention. The input/output device 1320 may include at least one selected from a keypad, a keyboard and a display device. The memory device 1330 is a device storing data. The memory device 1330 may store data and/or an instruction executed by the controller 1310. The memory device 1330 may include a volatile memory device and/or a nonvolatile memory device. The memory device 1330 may be formed by a flash memory. For example, a flash memory to which a technique of the present invention is applied may be built in a data processing system such as a mobile device or a desktop computer. The flash memory may be formed by a semiconductor disc device (SSD). In this case, the electronic system 1300 can stably store huge amounts of data in the flash memory system. The electronic system 1300 may further include an interface 1340 for transmitting data to a communication network or receiving data from a communication network. The interface 1340 may be a wire-wireless type. The interface 1340 may include an antenna or a wire-wireless transceiver. The electronic system 1300 may further include an application chip set, a camera image processor (CIS) and an input/output device.

The electronic system 1300 may be embodied by a mobile system, a personnel computer, an industrial computer or a logic system performing a variety of functions. For example, the mobile system may be one of a personal digital assistant (PDA), a portable computer, a web tablet, a mobile phone, a wireless phone, a laptop computer, a memory card, a digital music system and a data transmission/receipt system. When the electronic system 1300 is equipment capable of performing a wireless communication, the electronic system 1300 may be used in a third generation communication interfacing protocol such as CDMA, GSM, NADC, E-TDMA, and CDMA2000.

FIG. 7 is a block diagram illustrating an example of a memory card including a semiconductor package in accordance with an embodiment of the inventive concept.

The semiconductor device to which the technique of the present inventive concept is applied may be provided in the form of a memory card. Referring to FIG. 7, a memory card 1400 may include a nonvolatile memory device 1410 and a memory controller 1420. The nonvolatile memory device 1410 and the memory controller 1420 can store data or decode stored data. The nonvolatile memory device 1410 may include at least one of nonvolatile memory devices to which a technique of a semiconductor package according to the present inventive concept is applied. The memory controller 1420 can control the nonvolatile memory device 1410 so as to readout stored data or store data in response to a request of decoding/writing of a host 1430.

According to embodiments of the inventive concept, a manufacturing cost can be reduced by using an inexpensive aluminum in lieu of gold in the surface treatment for the package substrate.

According to embodiments of the inventive concept, the package substrate surface-treated with aluminum can be wire-bonded to the semiconductor chip. Through the wire bonding process, the bonding wire can penetrate the aluminum oxide layer formed on the contact pad to electrically connect the package substrate and the contact pad.

What is claimed is:

1. A package substrate comprising:
an insulating substrate having a top surface and a bottom surface;
a circuit pattern is disposed on at least one of the top surface and the bottom surface of the insulating substrate; and
a multilayer conductive joint unit disposed on the circuit pattern,
wherein the multilayer conductive joint unit comprises:
a nickel layer in contact with the circuit pattern; and
an aluminum layer on the nickel layer and electrically connected to a semiconductor chip mounted on the insulating substrate.

2. The package substrate of claim 1, wherein the multilayer conductive joint unit further comprises a metal layer between the nickel layer and the aluminum layer.

3. The package substrate of claim 2, wherein the metal layer comprises titanium (Ti), tantalum (Ta), titanium nitride (TiN), tantalum nitride (TaN), gold (Au), silver (Ag), or tungsten (W).

4. The package substrate of claim 1, wherein a thickness of the aluminum layer is 0.1 μm˜1 μm.

5. The package substrate of claim 1, wherein the insulating substrate comprises:
a core unit;
an upper interconnection layer disposed on a top surface of the core unit,
an upper insulating layer disposed on the upper interconnection layer,
a lower interconnection layer disposed on a bottom surface of the core unit, and
a lower insulating layer disposed on the lower interconnection layer.

6. The package substrate of claim 1, wherein the nickel layer is provided to cover a top surface and a side surface of the circuit pattern.

7. The package substrate of claim 1, wherein the nickel layer is provided to cover a part of a top surface of the circuit pattern.

8. The package substrate of claim 1, wherein the insulating substrate further comprises a solder resist layer disposed on the circuit pattern,
wherein the solder resist layer has a hole exposing a part of the circuit pattern.

9. The package substrate of claim 8, wherein the nickel layer and the aluminum layer are disposed inside the hole.

10. The package substrate of claim 1, wherein the package substrate comprises a PCB (printed circuit board) or a flexible substrate.

11. A package substrate comprising:
a substrate having a copper pad, an insulating layer, and a multilayer conductive joint unit, wherein the copper pad is disposed at a top surface of the insulating layer, and wherein the multilayer conductive joint unit includes a nickel layer in contact with the copper pad and a contact pad disposed on the nickel layer;
wherein the contact pad includes metallic compound including aluminum.

12. The package substrate of claim 11, wherein the contact pad is made of Al or Al—Cu.

13. The package substrate of claim 11, wherein the multilayer conductive joint unit further comprises a metal layer disposed between the nickel layer and the contact pad, and
wherein the metal layer comprises titanium (Ti), tantalum (Ta), titanium nitride (TiN), tantalum nitride (TaN), gold (Au), silver (Ag), or tungsten (W).

14. The package substrate of claim 11, wherein the multilayer conductive joint unit further comprises an aluminum oxide layer formed on a top surface of the contact pad.

15. The package substrate of claim 14, wherein the package substrate further comprises a semiconductor chip mounted on the package substrate,
wherein the semiconductor chip is electrically connected to the package substrate by a bonding wire,
wherein the bonding wire penetrates the aluminum oxide layer to electrically connect the contact pad and the semiconductor chip.

16. The package substrate of claim 11, wherein the package substrate further comprises a solder resist layer disposed on the copper pad and the insulating layer,
wherein the solder resist layer includes a hole to expose a part of the copper pad and wherein a sidewall of the hole surround the multilayer conductive joint unit.

17. A package substrate comprising:
a core unit,
an insulation layer disposed on the core unit,
a circuit pattern disposed on the insulation layer, and
a multilayer conductive joint unit disposed on the circuit pattern, wherein the multilayer conductive joint unit includes a bottom conductive layer and an contact pad and wherein the bottom conductive layer is in contact with the circuit pattern;
wherein the contact pad includes aluminum compound.

18. A package substrate of claim 17, wherein the bottom layer of the multilayer conductive joint unit comprises a nickel layer, and wherein the multilayer conductive joint further includes a middle metal layer between the nickel layer and the contact pad to increase an adhesive strength between the nickel layer and the contact pad.

19. A package substrate of claim 18, further comprising a solder resist layer disposed on the circuit pattern, wherein the solder resist layer includes a hole exposing a top surface and a side surface of a pad of the circuit pattern, and wherein the nickel layer covers the top surface and the side surface of the pad of the circuit pattern, the contact pad covers a top and a side surface of the nickel layer such that a side surface of the contact pad contacts a sidewall of the hole.

20. A package substrate of claim 17, wherein the contact pad is made of Al, Al—Cu, Al—Si or Al—Cu-Si.
